(19) United States
(12) Patent Application Publication
(10) Pub. No.: US 2008/0303565 A1
(43) Pub. Date: Dec. 11, 2008

(54) DLL CIRCUIT AND RELATED METHOD FOR AVOIDING STUCK STATE AND HARMONIC LOCKING UTILIZING A FREQUENCY DIVIDER AND AN INVERTER

(76) Inventor: Yen-Hsun Hsu, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/759,948

(22) Filed: Jun. 8, 2007

(51) Int. Cl. H03L 7/06

(52) U.S. Cl. 327/157; 327/156

(57) ABSTRACT

Disclosed is a DLL circuit for avoiding stuck and harmonic locking errors by utilizing a frequency divider and an inverter. This DLL circuit includes: a delay line, a control circuit, a first frequency divider, a second frequency divider and an inverter. The delay line is utilized for receiving a first clock signal and delaying the first clock signal by a delay amount to generate a second clock signal. Additionally, the control circuit, which is coupled to the delay line, is utilized for controlling the delay line. The first frequency divider, which is coupled to the delay line and the control circuit, is utilized for receiving the first clock signal and dividing a frequency of the first clock signal according to a first frequency dividing factor to form a third clock signal.

### BACKGROUND

This invention relates to a DLL circuit and related method thereof, and more particularly, to a DLL circuit and related method for avoiding stuck state and harmonic locking.

In many kinds of circuits, a delay locked loop (DLL) circuit is utilized for synchronizing desired clock(s) to prevent errors resulting from non-synchronization.

Please refer to FIG. 1 in conjunction with FIG. 2. FIG. 1 is a block diagram illustrating a related art DLL circuit 100 and FIG. 2 is a schematic diagram illustrating the operation of the DLL circuit 100 shown in FIG. 1. The DLL circuit 100 includes a plurality of delay stages 101-107, a phase detector 109, a charge pump 111, and a loop filter 113. The delay stages 101-107 are used for delaying the input clock signal CKᵢₙ to generate an output clock signal CKₙ synchronized with the input clock CKᵢₙ. Conventionally, the delay stages 101-107 form a delay line. Furthermore, each of the delay stages 101-107 generate clock signals having different delay amounts, such as CK₁, CK₂ . . . shown in FIG. 2, where each of the clock signals CK₁, CK₂ . . . may be derived for other purposes if necessary. In this case, the number of delay stages is n, thus the delay amount of each delay stage 101-107 is the total delay amount between the input clock signal CKᵢₙ and the output clock signal CKn divided by n.

Conventionally, the phase detector 109, the charge pump 111, and the loop filter 113 form a control circuit for controlling the delay stages 101-107. The phase detector 109 is utilized for comparing the input signal CKᵢₙ with the output signal CKₙ to generate a rising signal Up and a falling signal Dn. The rising signal Up and the falling signal Dn inform the charge pump 111 and the loop filter 113 to generate a control voltage V_{ctrl} for controlling the operation of the delay stages 101-107. Since the operation of the charge pump 111 and the loop filter 113 is well known to persons skilled in the art, further description is omitted for brevity. In this way, the delay amount of the delay stages 101-107 may be adjusted to enable the output signal CKₙ to synchronize with the input signal CKᵢₙ; that is, the delay amount D₁ between the input clock signal CKᵢₙ and the output clock signal CKn is equal to one period of the input clock signal CKᵢₙ. However, this kind of DLL circuit may suffer from several problems, which are described below.

FIG. 3 is a schematic diagram illustrating a stuck state of the DLL circuit 100 shown in FIG. 1. In FIG. 3, the delay amount D₂ between the input clock signal CKᵢₙ and the output clock signal CKₙ is less than ½ period of the input clock signal CKᵢₙ. In this case, the edge Y₄ of the output signal CKₙ will be wrongly adjusted by the phase detector 109, the charge pump 111, and the loop filter 113 to synchronize with the edge Y₃ of the input clock signal CKᵢₙ. This is known as stuck state.

FIG. 4 is a schematic diagram illustrating harmonic locking of the DLL circuit 100 shown in FIG. 1. As shown in FIG. 4, the delay between the input clock signal CKᵢₙ and the output clock signal CKₙ is larger than 1.5 periods of the input clock signal CKᵢₙ. In this case, the edge Y₅ of the input clock signal CKᵢₙ will be erroneously adjusted to synchronize with the edge Y₆ of the output clock signal CKₙ. This is known as harmonic locking.

Both stuck state and harmonic locking will cause the system serious problems. In order to solve these problems, some related art DLL circuits utilize a frequency divider and an inverter, however, these kinds of DLL circuits may have phase related problems. Thus, timing of rising and falling edges of the delayed clock signals is a great concern for this kind of DLL circuit. A novel and improved scheme is needed to solve these problems.

### SUMMARY

It is therefore one of the many objectives of the present invention to provide a DLL circuit for avoiding stuck state and harmonic locking using a frequency divider and an inverter.

Additionally, another objective of the present invention is to provide a DLL circuit with at least one switch device to prevent the input clock signal from passing unnecessary devices.

According to the claimed disclosure, a DLL circuit for avoiding stuck state and harmonic locking by using a frequency divider and an inverter is disclosed. This DLL circuit includes: a delay line, a control circuit, a first frequency divider, a second frequency divider and an inverter. The delay line is utilized for receiving a first clock signal and delaying the first clock signal by a delay amount to generate a second clock signal. Additionally, the control circuit, which is coupled to the delay line, is utilized for controlling the delay line. The first frequency divider, which is coupled to the delay line and the control circuit, is utilized for receiving the first clock signal and dividing a frequency of the first clock signal according to a first frequency dividing factor to form a third clock signal.

Additionally, the second frequency divider, which is coupled to the delay line and the control circuit, is utilized for receiving the second clock signal outputted from the delay line and dividing a frequency of the second clock signal according to a second frequency dividing factor to form a fourth clock signal, wherein the first frequency dividing factor is equal to the second frequency dividing factor. Furthermore, the inverter, which is coupled between the first frequency divider and the control circuit, is utilized for inverting the third clock signal to generate an inverted third clock signal. In this case, the control circuit compares the inverted third clock signal and the fourth clock signal to output a control signal for controlling the delay line, thereby locking the fourth clock signal to the inverted third clock signal.

According to the claimed disclosure, another DLL circuit for avoiding stuck state and harmonic locking by using a frequency divider and an inverter is also disclosed. The DLL circuit includes: a delay line, a control circuit, a first frequency divider, a second frequency divider and an inverter. The delay line is utilized for receiving a first clock signal and delaying the first clock signal by a delay amount to generate a second clock signal. Additionally, the control circuit, which is coupled to the delay line, is used for controlling the delay line. The first frequency divider, which is coupled to the delay line and the control circuit, is utilized for receiving the first clock signal and dividing a frequency of the first clock signal according to a first frequency dividing factor to form a third clock signal. The second frequency divider, which is coupled to the delay line and the control circuit, is utilized for receiving the second clock signal outputted from the delay line and dividing a frequency of the second clock signal according to a second frequency dividing factor to form a fourth clock signal, wherein the first frequency dividing factor is equal to the second frequency dividing factor. Furthermore, the inverter, which is coupled between the second frequency divider and the control circuit, is utilized for inverting the fourth clock signal to generate an inverted fourth clock signal. In this case, the control circuit compares the inverted fourth clock signal and the third clock signal to output a control signal for controlling the delay line, thereby locking the third clock signal to the inverted fourth clock signal.

A method corresponding to the above-mentioned DLL circuits is disclosed. This method includes: delaying the first clock signal by a delay amount to form the second clock signal; dividing a frequency of the first clock signal according to a first frequency dividing factor to form a third clock signal; dividing a frequency of the second clock signal according to a second frequency dividing factor to form a fourth clock signal, wherein the first frequency dividing factor is equal to the second frequency dividing factor; inverting one of the third clock signal and the fourth clock signal to generate an inverted clock signal while making the other a non-inverted clock signal; and utilizing a control circuit to compare the inverted clock signal and the non-inverted clock signal to output a control signal for controlling the delay amount, thereby locking the non-inverted clock signal to the inverted clock signal.

According to the claimed disclosure, still another DLL circuit for avoiding stuck state and harmonic locking by using a frequency divider and an inverter is disclosed. This DLL circuit includes a frequency divider, a delay line, an inverter, a control circuit, and a switch device. The frequency divider is utilized for receiving a first clock signal and dividing a frequency of the first clock signal to form a second clock signal. The delay line, which is coupled to the frequency divider, is utilized for receiving the second clock signal and delaying the second clock signal by a delay amount to generate a third clock signal. Additionally, the inverter, which is coupled to the frequency divider, is utilized for receiving the second clock signal to form an inverted second clock signal. Furthermore, a control circuit, which is coupled to the inverter and the delay line, is utilized for comparing the inverted second clock signal and the third clock signal to output a control signal for controlling the delay line, thereby locking the third clock signal to the inverted second clock signal. The switch device, which is coupled to the frequency divider, the delay line and the control circuit, is utilized for allowing the first clock signal to enter the frequency divider before the third clock signal is locked to the inverted second clock signal and for allowing the first clock signal to enter the control circuit and the delay line after the third clock signal is locked to the inverted second clock signal.

According to the claimed disclosure, still another DLL circuit for avoiding stuck and harmonic locking by using a frequency divider and an inverter is further disclosed. This DLL circuit includes a frequency divider, a delay line, an inverter, a control circuit, and a switch device. The frequency divider is utilized for receiving a first clock signal and dividing a frequency of the first clock signal to form a second clock signal. The delay line, which is coupled to the frequency divider, is utilized for receiving the second clock signal and delaying the second clock signal by a delay amount to generate a third clock signal. The inverter, which is coupled to the delay line, is utilized for receiving the third clock signal to form an inverted third clock signal. Furthermore, the control circuit, which is coupled to the inverter and the delay line, is utilized for comparing the inverted third clock signal and the second clock signal to output a control signal for controlling the delay line, thereby locking the second clock signal to the inverted third clock signal. The switch device, which is coupled to the frequency divider, the delay line and the control circuit, is utilized for allowing the first clock signal to enter the frequency divider before the second clock signal is locked to the inverted third clock signal and for allowing the first clock signal to enter the control circuit and the delay line after the second clock signal is locked to the inverted third clock signal.

A method corresponding to these two DLL circuits is also disclosed. The method includes: dividing the first clock signal to form a second clock signal; utilizing a delay line for delaying the second clock signal by a delay amount to form the third clock signal; inverting one of the second clock signal and the third clock signal to generate an inverted clock signal while making the other a non-inverted clock signal; utilizing a control circuit to compare the inverted clock signal and the non-inverted clock signal to output a control signal for controlling the delay line, thereby locking the non-inverted clock signal to the inverted clock signal; allowing the first clock signal to enter the frequency divider before the non-inverted clock signal is locked to the inverted clock signal; and allowing the first clock signal to enter the delay line and the control circuit after the non-inverted clock signal is locked to the inverted clock signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a related art DLL circuit.

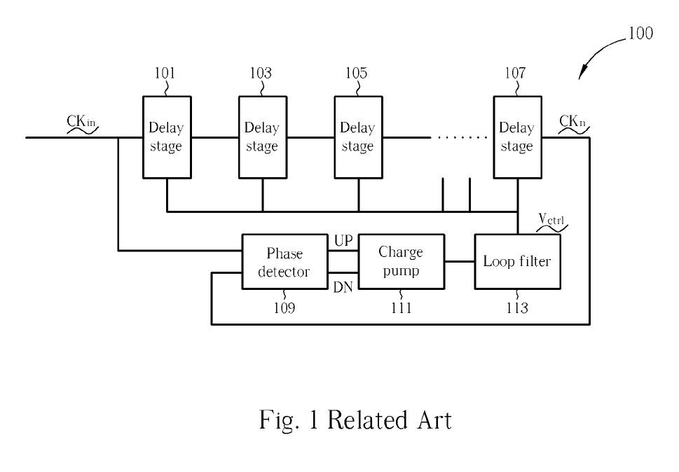

FIG. 2 is a timing diagram illustrating the normal operation of the DLL circuit shown in FIG. 1.

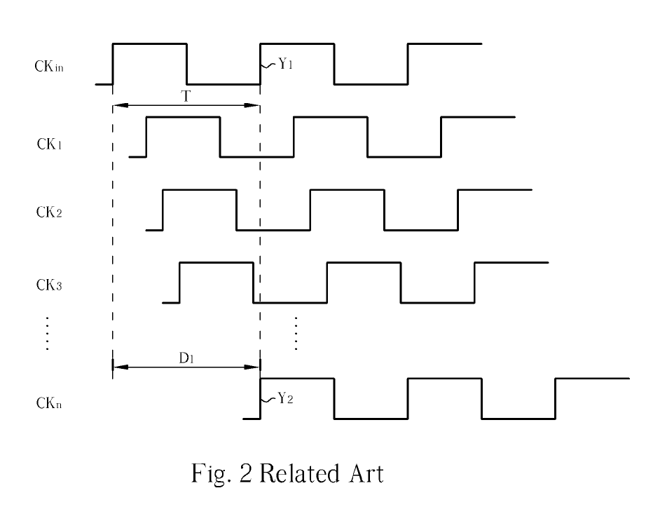

FIG. 3 is a timing diagram illustrating a stuck state of the DLL circuit shown in FIG. 1.

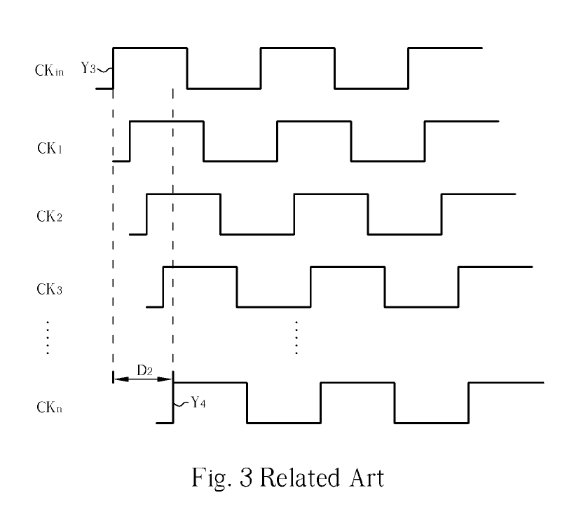

FIG. 4 is a timing diagram illustrating harmonic locking of the DLL circuit shown in FIG. 1.

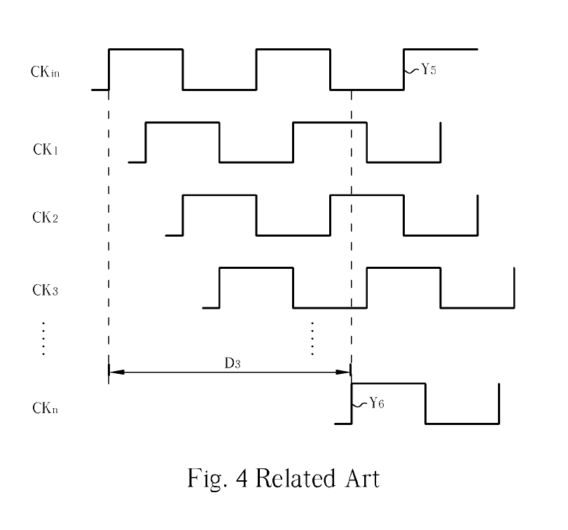

FIG. 5 is a block diagram illustrating a DLL circuit according to a first embodiment of the present invention.

FIG. 6 is a timing diagram illustrating the operation of the DLL circuit shown in FIG. 5.

FIG. 7 is a block diagram illustrating a DLL circuit shown according to a second embodiment of the present invention.

FIG. 8 is a block diagram illustrating a DLL circuit according to a third embodiment of the present invention.

FIG. 9 is a timing diagram illustrating the operation of the DLL circuit shown in FIG. 8.

FIG. 10 is a block diagram illustrating a DLL circuit according to a fourth embodiment of the present invention.

FIG. 11 is a flow chart illustrating a method performed by the DLL circuits shown in FIG. 5 and FIG. 8.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

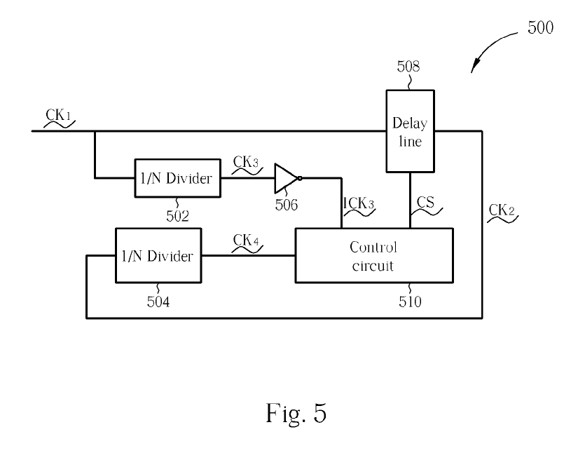

FIG. 5 is a block diagram illustrating a DLL circuit 500 according to a first embodiment of the present invention. The DLL circuit 500 includes a first frequency divider 502, a second frequency divider 504, an inverter 506, a delay line 508 and a control circuit 510. The delay line 508, which commonly includes a plurality of delay stages, is used for receiving a first clock signal CK₁ and delaying the first clock signal CK₁ by a delay amount to generate a second clock signal CK₂. In this embodiment, the control circuit 510 is used for controlling the delay line 508. Additionally, the first frequency divider 502 is utilized for receiving the first clock signal CK₁ and dividing a frequency of the first clock signal CK₁ according to a first frequency dividing factor to form a third clock signal CK₃. Furthermore, the second frequency divider 504 is used for receiving the second clock signal CK₂ outputted from the delay line 508 and dividing a frequency of the second clock signal CK₂ according to a second frequency dividing factor to form a fourth clock signal CK₄, wherein the first frequency dividing factor is equal to the second frequency dividing factor. The inverter 506 is used for inverting the third clock signal CK₃ to generate an inverted third clock signal ICK₃. The control circuit 510 then compares the inverted third clock signal ICK₃ and the fourth clock signal CK₄ to output a control signal CS for controlling the delay line 508, thereby locking the fourth clock signal CK₄ to the inverted third clock signal ICK₃.

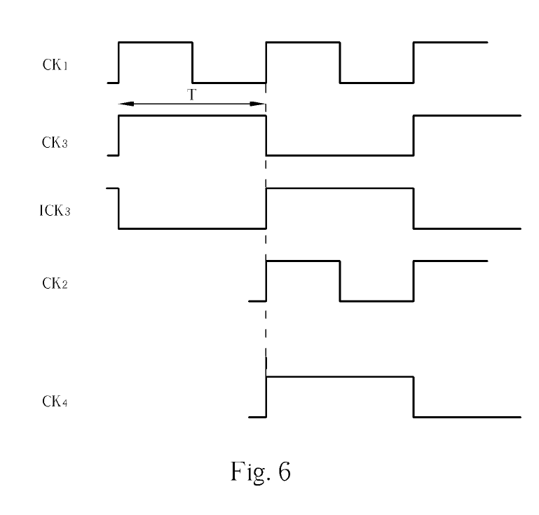

FIG. 6 is a timing diagram illustrating the operation of the DLL circuit 500 shown in FIG. 5. As shown in FIG. 6, the third clock signal CK₃ is generated from the first clock signal CK₁ frequency-divided by the first frequency divider 502. In this case for illustration, the frequency dividing factor N of the first frequency divider 502 is set to 2, thus the period of the third clock signal CK₃ is twice that of the first clock signal CK₁. The inverted third clock signal ICK₃ is generated through inverting the third clock signal CK₃ by the inverter 506.

When the DLL starts to function, the delay of the delay line 508 is set to minimum. This initial setting makes the delay time between the control circuit inputs ICK₃ and CK₄ larger than 0.5 T and smaller than 1 T. Then the control circuit 510 compares the inverted third clock signal ICK₃ and the clock signal CK₄ to make the rising edge of the fourth clock signal CK₄ locked to the rising edge of the inverted third clock signal ICK₃. Once CK₄ is locked to ICK₃, it means that the first clock signal CK₁ is locked to the second clock signal CK₂.

It should be noted that the control circuit 510 may include a phase detector, a charge pump, and a loop filter, as described above, but this modification does not limit the scope of the present invention. Similarly, although the frequency dividing ratios of the first and second frequency dividers of the present invention are set to 2, the frequency dividing ratios may be adjusted and set to other values as long as the duty of the divider's output is high for one period of the first clock signal CK₁.

In this way, the first embodiment of the present invention may avoid stuck state and harmonic locking. Moreover, since CK₁ is connected to the delay line 708 directly, the delay line 708 can produce multi-phase signals in the same frequency of CK₁ at the same time.

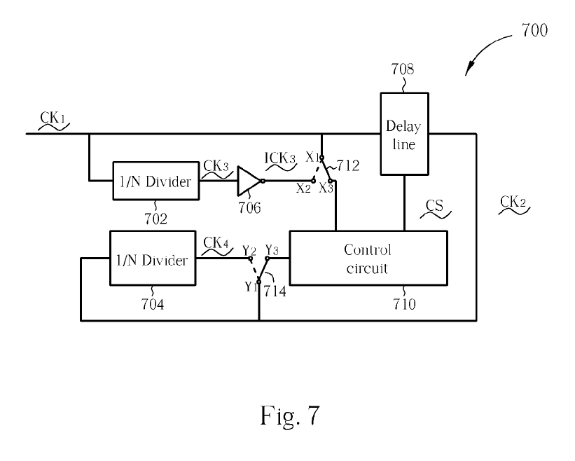

Furthermore, the DLL circuit according to the present invention has another advantage. FIG. 7 is a block diagram illustrating a DLL circuit 700 according to a second embodiment of the present invention. Similar to the DLL circuit 500 shown in FIG. 5, the DLL circuit 700 shown in FIG. 7 also includes a first frequency divider 702, a second frequency divider 704, an inverter 706, a delay line 708 and a control circuit 710. The difference between the DLL circuit shown 500 in FIG. 5 and the DLL circuit shown 700 in FIG. 7 is that the DLL circuit 700 further includes a first switch device 712 and a second switch device 714, where the first switch device 712 is located between the inverter 706, the delay line 708, and the control circuit 710, and the second switch device 714 is located between the first frequency divider 704, the delay line 708, and the control circuit 710, as shown in FIG. 7.

If the inverted third clock signal ICK₃ is not locked to the fourth clock signal CK₄, X2 and X3 are closed via the first switch device 712, and Y2 and Y3 are closed via the first switch device 714. In this case, the structure of the DLL circuit 700 is the same as that of the DLL circuit 500. Thus the operation of DLL circuit 700 is identical to that mentioned above.

If, however, the inverted third clock signal ICK₃ is locked to the fourth clock signal CK₄, X1 and X3 are closed via switch device 712 and Y1 and Y3 are closed via switch device 714. Therefore, the first clock signal CK₁ enters the control circuit 710 without passing the first frequency divider 702 and the inverter 706, and the second clock signal CK₂ enters the control circuit 710 without passing the second frequency divider 704. In this way, the clock signals do not need to pass unnecessary devices, and thus the jitter resulting from the mismatch between devices will decrease.

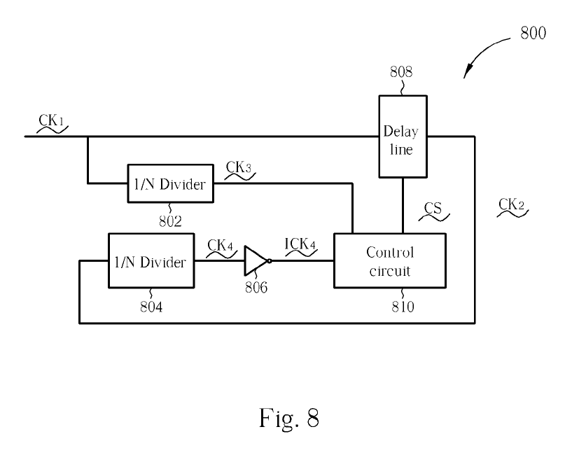

FIG. 8 is a block diagram illustrating a DLL circuit 800 according to a third embodiment of the present invention. Similar to the DLL circuit 500 shown in FIG. 5, the DLL circuit 800 includes a first frequency divider 802, a second frequency divider 804, an inverter 806, a delay line 808 and a control circuit 810. The difference between the DLL circuit 500 and the DLL circuit 800 is that the inverter 506 shown in FIG. 5 is located between the first frequency divider 502 and the control circuit 510, whereas the inverter 806 shown in FIG. 8 is located between the second frequency divider 804 and the control circuit 810.

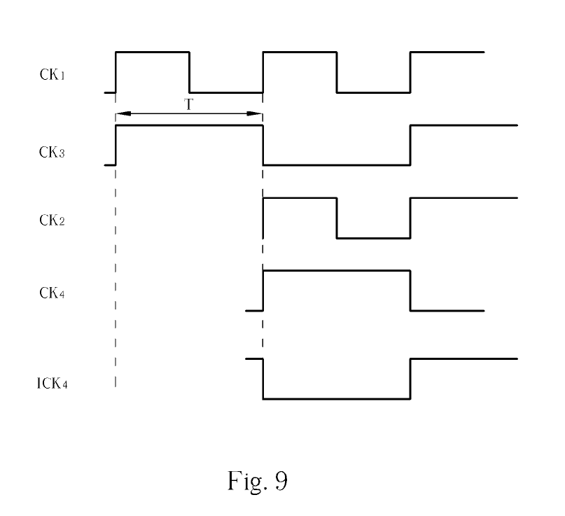

FIG. 9 is a schematic diagram illustrating the operation of the DLL circuit 800 shown in FIG. 8. As described above, the third clock signal CK₃ is generated from the first clock signal CK₁ frequency-divided by the first frequency divider 802, where the frequency dividing factor of the first frequency divider 802 is set to 2 in the third embodiment. The period of the third clock signal CK₃ is therefore twice that of the first clock signal CK₁. Furthermore, the fourth clock signal CK₄ is generated from the second clock signal CK₂ frequency-divided by the second frequency divider 804, where the frequency dividing factor of the second frequency divider 804 is the same as that set to the first frequency divider 802. The period of the fourth clock signal CK₄ is therefore twice that of the second clock signal CK₂. The inverted fourth clock signal ICK₄ is generated from the fourth clock signal CK₄ by the inverter 806.

The control circuit 810 make the falling edge of the third clock signal CK₃ locked to the falling edge of the inverted fourth clock signal ICK₄. As a result, The DLL circuit 800 makes the first clock signal CK₁ synchronous with the second clock signal CK₂.

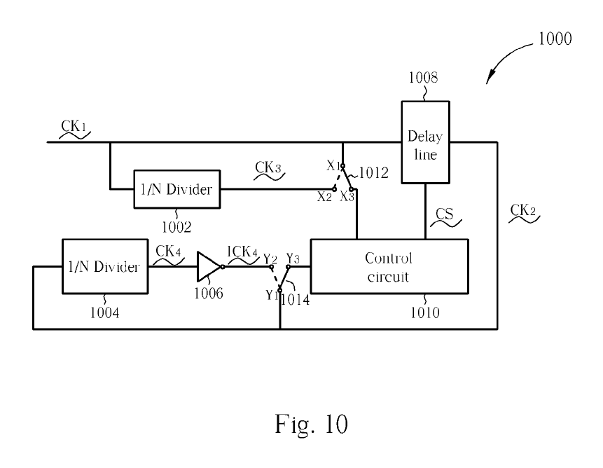

The DLL circuit shown in FIG. 8 may further include switches, as shown in FIG. 10. FIG. 10 is a block diagram illustrating a DLL circuit according to a fourth embodiment of the present invention. Similar to the DLL circuit 800 shown in FIG. 8, the DLL circuit 1000 shown in FIG. 10 also includes a first frequency divider 1002, a second frequency divider 1004, an inverter 1006, a delay line 1008 and a control circuit 1010. The difference between the DLL circuit 800 shown in FIG. 8 and the DLL circuit 1000 in FIG. 10 is that the DLL circuit 1000 further includes a first switch device 1012 and a second switch device 1014, where the first switch device 1012 is located between the first frequency divider 1002, the delay line 1008, and the control circuit 1010, and the second switch device 1014 is located between the inverter 1006, the delay line 1008, and the control circuit 1010, as shown in FIG. 10.

If the inverted fourth clock signal ICK₄ is not locked to the third clock signal CK₃, X₂ and X₃ are closed via the first switch device 1012, and Y₂ and Y₃ are closed via the first switch device 1014. In this case, the structure of the DLL circuit 1000 is the same as that of the DLL circuit 800. Thus the stuck- and harmonic-free operation of the DLL circuit 700 is identical to that previously described. However, if the inverted fourth clock signal ICK₄ is locked to the third clock signal CK₃, X₁ and X₃ are closed via the first switch device 1012, and Y₁ and Y₃ are closed via the first switch device 1014. Therefore, the first clock signal CK₁ enters the control circuit 1010 without passing the first frequency divider 1002, and the second clock signal CK₂ enters the control circuit 1010 without passing the second frequency divider 1004 and the inverter 1006. The benefit of such a configuration has been detailed above, and further description is thus omitted for brevity.

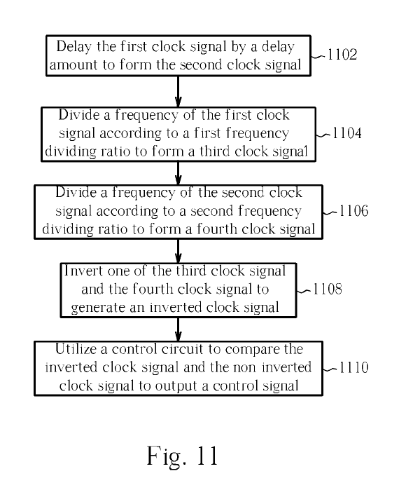

FIG. 11 is a flow chart illustrating a method performed by the DLL circuits shown in FIG. 5 and FIG. 8. This method includes: step 1102, delaying the first clock signal CK₁ by a delay amount to form a second clock signal CK₂; step 1104, dividing a frequency of the first clock signal CK₁ according to a first frequency dividing factor to form a third clock signal CK₃; step 1106, dividing a frequency of the second clock signal CK₂ according to a second frequency dividing factor to form a fourth clock signal CK₄, wherein the first frequency dividing factor is equal to the second frequency dividing factor; step 1108, inverting one of the third clock signal CK₃ and the fourth clock signal CK₄ to generate an inverted clock signal ICK while making the other a non-inverted clock signal NICK; step 1110, utilizing a control circuit to compare the inverted clock signal ICK and the non-inverted clock signal NICK to output a control signal for controlling the delay amount, thereby locking either the non-inverted clock signal NICK or the inverted clock signal ICK, according to which signal is generated from the second clock signal CK₂ (the fourth clock signal CK₄ in FIG. 5 and FIG. 7, the inverted fourth clock signal ICK₄ in FIG. 8 and FIG. 10), to the other signal. More clearly, either NICK is locked to ICK, or ICK is locked to NICK.

If this method corresponds to the circuit shown in FIG. 7 and FIG. 10, it further includes: allowing the inverted clock signal ICK and the non-inverted clock signal NICK to enter the control circuit before the non-inverted clock signal NICK is locked to the inverted clock signal ICK; and allowing the first clock signal CK₁ and the second clock signal CK2 to enter the control circuit when one of the non-inverted clock signal NICK and the inverted clock signal ICK is locked to the other.

Those skilled in the art will readily observe that numerous modifications and alterations of the device and method may be made while retaining the teachings of the invention. Accordingly, the above disclosure should be construed as limited only by the metes and bounds of the appended claims.

1. The delay lock loop of claim 14, wherein the inverter is coupled between the first frequency divider and the control circuit, and utilized for inverting the third clock signal to generate the inverted clock signal.

2. The DLL circuit of claim 1, further comprising:
a first switch device, coupled to the delay line, the control circuit and the inverter, for allowing the inverted clock signal to enter the control circuit before the fourth clock signal is locked to the inverted clock signal and for allowing the first clock signal to enter the control circuit after the fourth clock signal is locked to the inverted clock signal; and
a second switch device, coupled to the control circuit and the second frequency divider, for allowing the fourth clock signal to enter the control circuit before the fourth clock signal is locked to the inverted clock signal and for allowing the second clock signal to enter the control circuit after the fourth clock signal is locked to the inverted clock signal

3. The DLL circuit of claim 1, wherein the delay line comprises a plurality of delay stages, and a delay amount of each delay stage is controlled by the control signal.

4. The DLL circuit of claim 1, wherein the control circuit comprises a phase detector, a charge pump and a loop filter.

5. The DLL circuit of claim 1, wherein the control signal is a voltage or a current.

6. The delay lock loop of claim 14, wherein the inverter is coupled between the second frequency divider and the control circuit, and utilized for inverting the fourth clock signal to generate the inverted clock signal.

7. The DLL circuit of claim 6, further comprising:
a first switch device, coupled to the delay line, the control circuit and the first frequency divider, for allowing the third clock signal to enter the control circuit before the third clock signal is locked to the inverted clock signal and for allowing the first clock signal to enter the control circuit after the third clock signal is locked to the inverted clock signal; and
a second switch device, coupled to the control circuit and the inverter, for allowing the inverted clock signal to enter the control circuit before the third clock signal is locked to the inverted clock signal and for allowing the second clock signal to enter the control circuit after the third clock signal is locked to the inverted clock signal.

8. The DLL circuit of claim 6, wherein the delay line comprises a plurality of delay stages, and a delay amount of each delay stage is controlled by the control signal.

9. The DLL circuit of claim 6, wherein the control circuit comprises a phase detector, a charge pump and a loop filter.

10. The DLL circuit of claim 6, wherein the control signal is a voltage or a current.

11. A method for locking a second clock signal to a first clock signal, comprising:
delaying the first clock signal by a delay amount to form the second clock signal;
dividing a frequency of the first clock signal according to a first frequency dividing factor to form a third clock signal;
dividing a frequency of the second clock signal according to a second frequency dividing factor to form a fourth clock signal, wherein the first frequency dividing factor is equal to the second frequency dividing factor;
inverting one of the third clock signal and the fourth clock signal to generate an inverted clock signal while making the other a non-inverted clock signal;
utilizing a control circuit to compare the inverted clock signal and the non-inverted clock signal to output a control signal for controlling the delay amount, thereby either locking the non-inverted clock signal to the inverted clock signal, or locking the inverted clock signal to the non-inverted clock signal, according to which signal is generated from the second clock signal.

12. The method of claim 11, further comprising:
allowing the inverted clock signal and the non-inverted clock signal to enter the control circuit before the non-inverted clock signal is locked to the inverted clock signal; and
allowing the first clock signal and the second clock signal to enter the control circuit after the non-inverted clock signal is locked to the inverted clock signal.

13. The method of claim 11, wherein the control signal is a voltage or a current.

14. A delay locked loop (DLL) circuit, comprising:
a delay line for receiving a first clock signal and delaying the first clock signal by a delay amount to generate a second clock signal;
a control circuit, coupled to the delay line, for controlling the delay line;
a first frequency divider, coupled to the control circuit, for receiving the first clock signal and dividing a frequency of the first clock signal according to a first frequency dividing factor to form a third clock signal;
a second frequency divider, coupled to the delay line and the control circuit, for receiving the second clock signal outputted from the delay line and dividing a frequency of the second clock signal according to a second frequency dividing factor to form a fourth clock signal, wherein the first frequency dividing factor is equal to the second frequency dividing factor; and
an inverter, coupling one of the first frequency divider and the second frequency divider to the control circuit, for inverting one of the third clock signal and the fourth clock signal to generate an inverted clock signal while making the other a non-inverted clock signal;
wherein the control circuit compares the inverted clock signal and the non-inverted clock signal to output a control signal for controlling the delay line, thereby either locking the non-inverted clock signal to the inverted clock signal, or locking the inverted clock signal to the non-inverted clock signal, according to which signal is generated from the second clock signal.
